(19) United States
(12) Patent Application Publication
(10) Pub. No.: US 2002/0024834 A1
(43) Pub. Date: Feb. 28, 2002

(54) Memory module having programmable logic device and sTSOP

(75) Inventors: Jun-Young Jeon, Seoul (KR); Chul-Hong H Park, Kyungki-do (KR); Gyou-Joong Kim, Seoul (KR)

Correspondence Address: MARGER JOHNSON & McCOLLOM, P.C., 1030 S.W. Morrison Street, Portland, OR, 97205, US

(73) Assignee: Samsung Electronics Co., Ltd., Suwon-city (KR)

(21) Appl. No.: 09/934,999

(22) Filed: Aug. 21, 2001

(30) Foreign Application Priority Data
Aug. 25, 2000 (KR) 00-49647

(51) Int. Cl. G11C 5/06

(52) U.S. Cl. 365/63; 365/51; 365/230.03

(57) ABSTRACT

A memory module on a printed circuit board (PCB) has double density without increasing the area and height thereof. The memory module includes a first memory bank and a second memory bank that share data lines on the PCB. Each bank includes a group of packaged semiconductor memory devices. The memory module of the invention additionally includes a programmable logic device (PLD). The PLD outputs signals that selectively enable one of the first and second banks, in response to a bank select signal and control signals received from a memory controller. The package of the plurality of semiconductor memory devices is a shrink Thin Small Outline Package (sTSOP) or a chip size package (CSP) or plastic in which a length and a width are similar to each other.

This application claims priority from Korean Priority Document No. 00-49647, filed on Aug. 25, 2000 with the Korean Industrial Property Office, which document is hereby incorporated by reference.

### BACKGROUND OF THE INVENTION

1. Field of the Invention

The present invention relates to a memory module, and more particularly, to a double-density memory module on a printed circuit board that uses a programmable logic device (PLD) to select between memory banks on the chip.

2. Description of the Related Art

High performance electronic systems and semiconductor memory devices require processing a large amount of data at high speed. It becomes correspondingly necessary to store large amounts of data.

Common methods for improving information storage capacity of a semiconductor device are to increase the integration density of the semiconductor device, and to use a high density memory module. To that end, a memory module is implemented in the prior art by placing the plurality of semiconductor devices packaged as a single unit on a printed circuit board. Such a printed circuit board is called “PCB”.

FIG. 1 is a block diagram showing a conventional memory module 10 on a PCB 15. FIG. 2 illustrates the arrangement of FIG. 1 in more detail. In addition, FIG. 2 shows a connector 17 for electrically coupling memory module 10 to a system board (not shown).

Referring to FIGS. 1 and 2, on PCB 15 there are placed a buffer 11, and a memory block 13. Memory block 13 composed of a plurality of memory devices 13-1, 13-2, . . . 13-7.

Signals /RAS, /CAS, A0-A12, /WE, /OE are generated from a memory controller (not shown), and then are input to the buffer 11 through the connector 17. The buffer 11 buffers signals /RAS, /CAS, A0-A12, /WE, and /OE and outputs the buffered result to the memory block 13. Then the memory block 13 receives and outputs data DQ through the connector 17 in response to the buffered result.

It is always desired to increase the memory. In a system supporting a conventional single bank memory module, a method of doubling the density of a system memory is to double the number of semiconductor memory devices having the same capacity, or to double the storage capacity of semiconductor devices.

Neither approach works well. One the one hand, mounting a memory device having twice the memory capacity increases the manufacturing cost. For example, it costs more to manufacture a semiconductor device having 128 megabytes (MB) than one having 64 MB.

One the other hand, a problem with doubling the number of semiconductor memory devices is that, to select one group, the design of a system is made difficult. This is because selects banks of the memory module 10 requires complicated design, in addition to increasing the number of signal pins for a bank select signal of a chipset within a system.

### SUMMARY OF THE INVENTION

To solve the above problems, it is an object of the present invention to provide a double-density memory module at a low manufacturing cost, and with easy system design.

Accordingly, to achieve the above objects, the present invention provides a memory module on a printed circuit board (PCB). The memory module includes a first memory bank and a second memory bank that share data lines on the PCB. Each bank includes a group of packaged semiconductor memory devices.

The memory module of the invention additionally includes a programmable logic device (PLD). The PLD outputs signals that selectively enable one of the first and second banks, in response to a bank select signal and control signals received from a memory controller.

A memory module having a PLD according to the invention reduces the number of control signals /RAS in a chipset by half, contrasted to a conventional memory module wherein the number of semiconductor memory devices having the same storage capacity is doubled. Thus, this not only cuts down the manufacturing cost but also makes a system design easier.

The package of the plurality of semiconductor memory devices may be a shrink Thin Small Outline Package (sTSOP) or a chip size package (CSP) or plastic in which a length and a width are similar to each other.

Furthermore, a memory module having a PLD according to the invention using sTSOP provides double memory module density within the same area as a PCB of the conventional memory module. The memory module reduces the manufacturing cost by doubling a low-density memory device (e.g., 64 MB) instead of using a double-density memory device (e.g., 128 MB).

### BRIEF DESCRIPTION OF THE DRAWINGS

The above objects and advantages of the present invention will become more apparent by describing in detail a preferred embodiment thereof with reference to the attached drawings in which:

FIG. 1 is a block diagram showing a conventional memory module on a PCB;

FIG. 2 illustrates an arrangement of the conventional memory module of FIG. 1;

FIG. 3 is a block diagram showing a memory module including a programmable logic device (PLD) made according to an embodiment of the present invention;

FIG. 4 illustrates arrangement of the memory module having the PLD according to the embodiment of the invention shown in FIG. 3; and

FIG. 5 is a table for implementing a logic of the PLD of FIG. 3 according to an embodiment of the invention.

FIG. 6 is a block diagram showing a memory module having a PLD than can apply to a synchronous dynamic random access memory (DRAM) according to another embodiment of the invention.

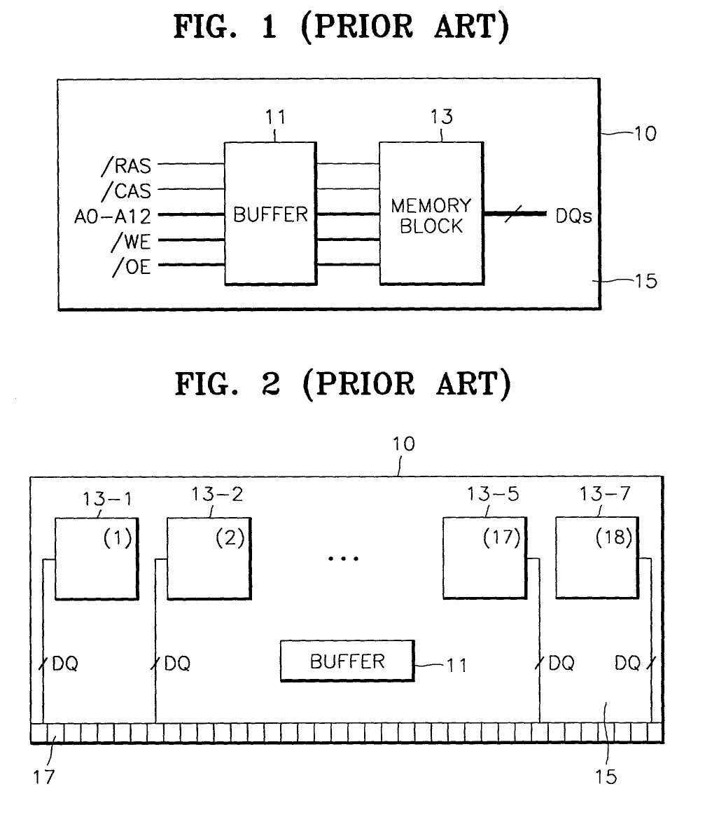

### DETAILED DESCRIPTION OF THE INVENTION

The present invention will now be described more fully with reference to the accompanying drawings, in which preferred embodiments of the invention are shown. The same reference numerals in different drawings represent the same element.

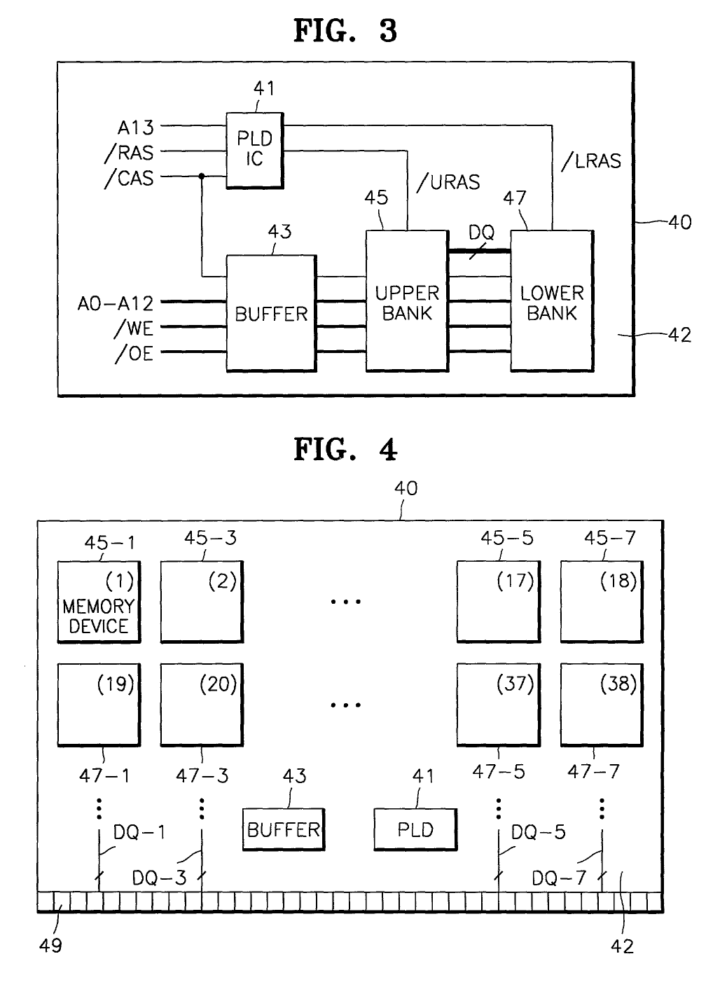

Referring to FIGS. 3 and 4, a memory module 40 is provided on a printed circuit board (PCB) 42 according to the invention. PCB 42 has a connector 49.

Memory module 40 includes a programmable logic device (PLD) 41. PLD 41 may advantageously be provided in the form of an integrated circuit (IC).

Memory module 40 also includes an upper memory bank 45, and a lower memory bank 47. Memory module 40 also includes a buffer 43 for buffering control signals for controlling upper memory bank 45, and a lower memory bank 47. The control signals are received from a memory controller (not shown) through the connector 49.

Referring to FIG. 4, an example is shown where the upper bank 45 is composed of 18 memory units (only four of which are shown explicitly and numbered) 45-1, 45-3, . . . , 45-5, and 45-7. In addition, the lower bank 47 is composed of 18 memory units (only four of which are shown explicitly and numbered) 47-1, 47-3, . . . , 47-5, and 47-7.

For both the upper bank 45 and the lower bank 47, each unit may be a 16 megabyte (MB)‘ 4 shrink Thin Small Outline Package (sTSOP). In this case, the sTSOP can be of half the size of a conventional thin small outline package (TSOP).

An important advantage of the invention is thus illustrated. While a board made according to the invention would have double the number of memory units, they can be of half size compared to those in the prior art for equal memory storage. Accordingly, there is substantially no penalty of increased area for practicing the invention.

Continuing to refer to FIG. 4, a set of 18 data lines (only four of which are shown explicitly and numbered) DQ-1, DQ-3, DQ-5, DQ-7 are provided, terminating in connector 49. Importantly, each set of data lines terminates in both the upper bank 45 and the lower bank 47. In other words, these data lines are shared, as can also be seen in FIG. 3. At any one time, they are used either by the upper bank 45 or by the lower bank 47 for inputting or outputting data DQ.

Referring now to FIG. 3, the buffer 43 buffers a second control signal /CAS (Column Address Strobe), address signals A0-A12, a write enable signal /WE, and an output enable signal /OE to output the buffered result to the upper bank 45 or the lower bank 47. The address signals A0-A12 are a signal for selecting a location of a memory cell which data DQ is read from or written to, and the write enable signal /WE is a signal for controlling the writing of data DQ to the memory cell selected by the address signals A0-A12. The output enable signal /OE is a signal for controlling the reading of data DQ from the memory cell selected by the address signals A0-A12.

The PLD 41 selectively enables the upper bank 45 or the lower bank 47 in response to a bank select signal A13, to a first control signal /RAS (Row Address Strobe), and to a second control signal /CAS. /RAS is a first control signal for strobing a row address, and /CAS is a second control signal for strobing a column address. The first control signal /RAS serves as a chip enable for controlling the entire DRAM, and the DRAM does not begin to operate until the first control signal /RAS is input at a logic low level. The second control signal /CAS is a signal indicating that a column address is applied to the DRAM.

The PLD 41 selects the upper bank 45 or the lower bank 47 by a combination of the first and second control signals /RAS and /CAS, and a bank select signal A13 to read and write data DQ, or refreshes the upper and lower banks 45 and 47. A signal /URAS serves as a chip enable for controlling the entire upper bank 45, and data DQ is written to or read from the upper bank 45 only after the signal /URAS is input at a logic low level. A signal /LRAS serves as a chip enable for controlling the entire lower bank 47, and data DQ is written to or read from the lower bank 47 only after the signal /LRAS is input at a logic low level.

The PLD 41 outputs the signals /URAS and /LRAS in response to the bank select signal A13, and the first and second control signals /RAS and /CAS. Specifically, the PLD 41 outputs the signal /LRAS in a first logic state (logic “low”, for example) and the signal /URAS in a second logic state (logic “high”, for example) in response to the first control signal /RAS in a first logic state (logic “low”, for example), the second control signal /CAS in a second logic state (logic “high”, for example), and the bank select signal A13 in a second logic state (logic “high”, for example).

Thus, the lower bank 47 is enabled in response to the signal /LRAS in the first logic state, in which case data DQ is input to and output from the lower bank 47. In another example, the first and second logic states may be logic “high” and logic “low” states, respectively.

The PLD 41 outputs the signal /LRAS in a second logic state (logic “high”, for example) and the signal /URAS in a first logic state (logic “low”, for example) in response to the first control signal /RAS in a first logic state (logic “low”, for example), the second control signal /CAS in a second logic state (logic “high”, for example), and the bank select signal A13 in a first logic state (logic “low”, for example). Thus, the upper bank 45 is enabled by the signal /URAS in a first logic state (logic “low”, for example), and data DQ is input to and output from the upper bank 45.

The PLD 41 outputs the signal /URAS in the first logic state and the signal /LRAS in the first logic state in response to the first control signal /RAS in the first logic state, the second control signal /CAS in the first logic state, and the bank select signal A13 in a don't care state. Thus, the upper and lower banks 45 and 47 are enabled. In this case, the upper and lower banks 45 and 47 receive a command CAS Before RAS (CBR) to be refreshed.

The PLD 41 outputs the signal /URAS in the second logic state and the signal /LRAS in the second logic state in response to the first control signal /RAS in the second logic state, and the second control signal /CAS and the bank select signal A13 in a don't care state. In this case, the upper and lower banks 45 and 47 do not operate.

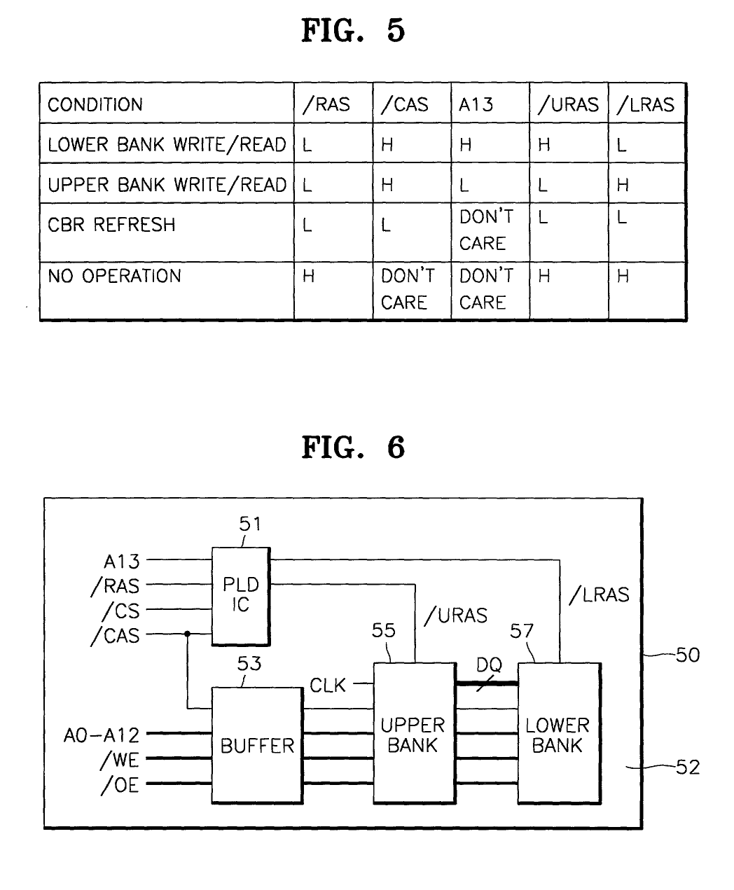

Referring to FIG. 5, a table is shown for implementing a logic of the PLD 41 according to an embodiment of the invention. After the upper bank 45 or the lower bank 47 are enabled by the first control signal /RAS, the upper bank 45 or the lower bank 47 is selected by the bank select signal A13. The upper bank 45 and the lower bank 47 are simultaneously refreshed, and if the first control signal /RAS is in a second logic state e.g., in a logic high state, they do not operate.

Referring now to FIG. 6 is a block diagram is shown of a memory module 50 on a PCB 52 according to another embodiment of the invention. Module 50 has a PLD that can also apply to a synchronous DRAM.

Module 50 includes a PLD 51, a buffer 53, an upper bank 55, and a lower bank 57. The PLD 51 selectively enables the upper bank 55 or the lower bank 57 in response to a combination of bank select signals A13 and /CS, and control signals /RAS and /CAS to read/write data DQ from/to the upper bank 55 or the lower bank 57, or to refresh the upper and lower banks 55 and 57. Thus, data DQ in the upper and lower banks 55 and 57 are written or read in synchronization with a system clock CLK. The bank select signal /CS is a signal for selecting a chip, i.e., upper or lower bank 55 or 57 in the synchronous DRAM. The other operations are similar to those shown in FIGS. 3 and 4, and a detailed explanation is therefore omitted to prevent repetition. The person skilled in the art will quickly discern the relevant table that is required for the PLD 51, and so on.

Various other embodiments of the invention are also possible. For example, a packaged plurality of semiconductor memory devices may be placed on a PCB, and each bank includes a plurality of semiconductor memory devices. Furthermore, the memory module has a plurality of banks and a PLD for selectively enabling one or more of the plurality of banks in response to a bank select signal and control signals received from a memory controller.

In the drawings and specification, there have been disclosed typical preferred embodiments of the invention and, although specific terms are employed, they are used in a generic and descriptive sense only and not for purpose of limitation. Thus, it will be understood by those skilled in the art that various changes in form and details may be made therein without departing from the spirit and scope of the invention as defined by the appended claims.

What is claimed is:

1. A memory module that uses memory units, each memory unit being a packaged plurality of semiconductor memory devices, the memory module comprising:
a printed circuit board (PCB);
a first bank of a first plurality of the memory units mounted on the PCB;
a second bank of a second plurality of the memory units mounted on the PCB; and
a programmable logic device mounted on the PCB for selectively enabling one of the first second banks in response to a bank select signal and control signals received from a memory controller.

2. The memory module of claim 1, wherein at least some of the memory units are shrink Thin Small Outline Packages.

3. The memory module of claim 1, wherein at least some of the memory units are chip size packages.

4. The memory module of claim 1, wherein at least some of the memory units are comprised of plastic in which a length and a width are substantially equal to each other.

5. The memory module of claim 1, wherein the control signals include a first control signal for strobing a row address and a second control signal for strobing a column address.

6. The memory module of claim 5, further comprising:
a buffer for buffering the second control signal but not the first control signal.

7. The memory module of claim 5, wherein the programmable logic device enables
the second bank when the first control signal is in a first logic state, the second control signal is in a second logic state, and the bank select signal is in a second logic state, and
the first bank when the first control signal is in the first logic state, the second control signal is in the second logic state, and the bank select signal is in the first logic state.

8. The memory module of claim 5, wherein the programmable logic device refreshes the first and second banks when the first and second control signals are in the first logic state.

9. The memory module of claim 5, wherein the programmable logic device disables the first and second banks when the first control signal in the second logic state.

10. A memory module that uses memory units, each memory unit being a packaged plurality of semiconductor memory devices, the memory module comprising:
a printed circuit board (PCB);
a plurality of banks, each bank being comprised of a plurality of the memory units mounted on the PCB; and
a programmable logic device mounted on the PCB for selectively enabling at least one among the plurality of banks in response to a bank select signal and control signals received from a memory controller.

11. The memory module of claim 10, wherein at least some of the memory units are shrink Thin Small Outline Packages.

12. The memory module of claim 10, wherein at least some of the memory units are chip size packages.

13. The memory module of claim 10, wherein at least some of the memory units are comprised of plastic in which a length and a width are substantially equal to each other.

14. The memory module of claim 10, wherein one of the control signals is a first control signal for strobing a row address and the other is a second control signal for strobing a column address.

15. The memory module of claim 14, further comprising:
a buffer for buffering the second control signal but not the first control signal.
